(19) United States
(12) Patent Application Publication
(10) Pub. No.: US 2008/0227268 A1
(43) Pub. Date: Sep. 18, 2008

(54) METHOD OF FORMING AN ISOLATION LAYER IN A SEMICONDUCTOR MEMORY DEVICE

(75) Inventor: Young Bok Lee, Icheon-si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-Si (KR)

(21) Appl. No.: 11/954,475

(22) Filed: Dec. 12, 2007

(30) Foreign Application Priority Data
Mar. 15, 2007 (KR) 10-2007-25485

(51) Int. Cl. H01L 21/762

(52) U.S. Cl. 438/425; 257/E21.546

(57) ABSTRACT

A method of forming an isolation layer in a semiconductor memory device is disclosed. After a trench is formed in a semiconductor substrate, a plasma nitrification annealing process is performed before and preferably after a wall oxide layer is formed to prevent trap charges and degradation problems at the interface and sidewalls of a tunnel insulating layer due to PSZ stress induced in a subsequent process. Accordingly, a variation in the ISPP step can be prevented.

### CROSS-REFERENCE TO RELATED APPLICATION

Priority to Korean patent application number 10-2007-25485, filed on Mar. 15, 2007, which is incorporated by reference in its entirety, is claimed.

### BACKGROUND OF THE INVENTION

The invention relates to a method of forming an isolation layer of a semiconductor memory device and, more particularly, to a method of forming an isolation layer of a semiconductor memory device using a plasma nitrification annealing process.

In semiconductor circuits, elements formed over a semiconductor substrate, such as transistors, diodes, resistors and so on, are electrically isolated. This isolation process is an initial process in semiconductor fabrication processes, and it controls the size of an active region and the process margin of subsequent steps.

As a method for such device isolation, local oxidation of silicon (LOCOS) has generally been used. However, according to such LOCOS device isolation, at the time of selective oxidization of a semiconductor substrate, oxygen penetrates from the bottom of a nitride layer, used as a mask, to the sides of a pad oxide layer, thereby generating a bird's beak structure at the ends of a field oxide layer. The bird's beak causes the field oxide layer to extend into an active region by an amount approximately equal to the length of the bird's beak, so that a channel length is shortened and the threshold voltage is increased. Consequently, a problem arises because the electrical characteristics of transistors, etc. are degraded.

Alternatively, a shallow trench isolation (hereinafter, referred to “STI”) process can be used as an isolation process. The STI process can solve problems such as instability factors in a process (for example, degradation of a field oxide layer according to a reduction in the design rule of a semiconductor device), and a reduction in an active region due to the formation of a bird's beak structure.

FIG. 1 is a cross-sectional view illustrating a method of forming an isolation layer in a conventional semiconductor memory device.

Referring to FIG. 1, a conventional STI type isolation layer is formed by sequentially forming a screen oxide layer 101 and a nitride layer 102 over a semiconductor substrate 100, selectively etching the screen oxide layer 101, the nitride layer 102 and the semiconductor substrate 100 to form trenches 100a, filling the trenches with O₃-TEOS (Tetraethylorthosilicate) to form an isolation layer 103, and then performing an annealing process.

However, the above process may have a problem in that voids 104 and seams 105 remain within the isolation layer 103. The isolation layer 103 can formed using polysilazane (PSZ) with a good gap-fill ability to prevent the formation of the voids 104 and the seams 105.

If the isolation layer 103 is formed of the PSZ film, ISPP (incremental step-pulse programming) step variation occurs because of trap charges and degradation at the interface and sidewalls of the screen oxide layer 101 due to stress caused by the PSZ film. Consequently, a problem may arise because the distributions of the threshold voltage of a memory cell are widened.

FIGS. 2A and 2B are graphs illustrating the FN (Fowler-Nordheim) current of a tunnel oxide layer in the prior art. From FIGS. 2A and 2B, it can be seen that the FN current varies at a program bias and an erase bias.

### BRIEF SUMMARY OF THE INVENTION

The invention is directed to a method of forming an isolation layer in a semiconductor memory device. In the method, once a trench is formed in a semiconductor substrate, a plasma nitrification annealing process is performed before and preferably after a wall oxide layer is formed to prevent trap charges and degradation problems at the interface and sidewalls of a tunnel insulating layer due to PSZ stress induced in a subsequent process, thus preventing ISPP step variation.

In one embodiment, a method of forming an isolation layer in a semiconductor memory device includes: forming a tunnel insulating layer and a conductive layer for a floating gate over a semiconductor substrate; selectively etching the conductive layer, the tunnel insulating layer, and the semiconductor substrate to form a trench; performing a plasma nitrification annealing process; forming a first insulating layer over the entire resulting surface including the trench; depositing a second insulating layer over the entire resulting surface including the first insulating layer; and performing a curing process.

The method preferably further includes after the plasma nitrification annealing process and before forming the first insulating layer: forming a wall oxide layer over the entire resulting surface including the trench; and performing a second plasma nitrification annealing process.

The method preferably further includes performing a post-annealing process before the first insulating layer is formed and after the plasma nitrification annealing process. The post-annealing process preferably includes using an N₂ gas at a temperature of 800 degrees Celsius to 900 degrees Celsius for 20 minutes to 30 minutes.

Preferably, the plasma nitrification annealing process includes using an Ar gas and an N₂ gas at a temperature of 400 degrees Celsius to 500 degrees Celsius. Prefereably, the plasma nitrification annealing process includes using a bias power of 1.8 kW to 3.3 kW at a pressure of 200 mT to 500 mT for 5 sec to 30 sec. Preferably, the plasma nitrification annealing includes using the Ar gas and the N₂ gas at flow rates selected such that the ratio of the flow rate of the Ar gas to the flow rate of the N₂gas is 1:0.2 to 0.5.

The first insulating layer preferably includes a HDP (high density plasma) oxide layer, and the second insulating layer is preferably selected from the group consisting of an SOG (spin-on glass) layer, a PSG (phosphosilicate glass) layer, and a BPSG (boron-doped phosphosilicate glass) layer.

Preferably, the method further includes, after forming the conductive layer: forming a buffer oxide layer, a pad nitride layer, and a hard mask layer over the conductive layer; wherein the step of selective etching further comprises using the hard mask pattern as a mask to sequentially etch the pad nitride layer the buffer oxide layer, the conductive layer, the tunnel insulating layer, and the semiconductor substrate when forming the trench.

In an additional embodiment, a method of forming an isolation layer in a semiconductor memory device includes: forming a tunnel insulating layer on a semiconductor substrate; etching the tunnel insulating layer and an isolation region of the semiconductor substrate to form a trench; performing a plasma nitrification annealing process to prevent trap charges and degradation at an interface and at sidewalls of the tunnel insulating layer; forming a first insulating layer over the entire resulting surface including the trench; depositing a second insulating layer over the entire resulting surface including the first insulating layer; and performing a curing process.

### BRIEF DESCRIPTION OF THE DRAWINGS

FIG. 1 is a cross-sectional view illustrating a method of forming an isolation layer in a conventional semiconductor memory device;

FIGS. 2A and 2B are graphs illustrating the FN current of a tunnel oxide layer in the prior art;

FIGS. 3 to 6 are cross-sectional views illustrating a method of forming an isolation layer of a semiconductor memory device according to an embodiment of the invention; and

FIGS. 7A and 7B are graphs illustrating the FN current of a tunnel insulation layer according to an embodiment of the invention.

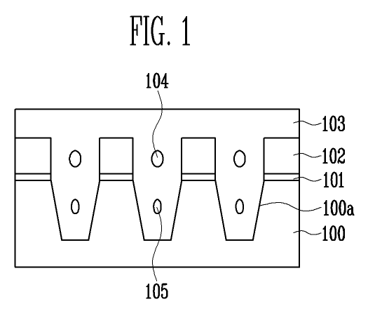

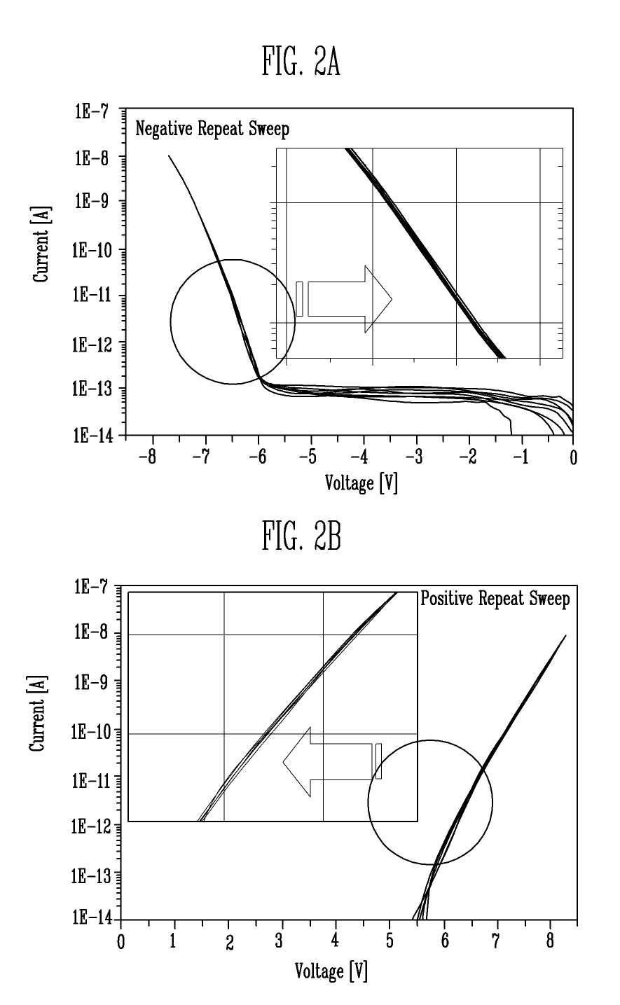

### DESCRIPTION OF SPECIFIC EMBODIMENTS

Now, a specific embodiment according to the invention is described with reference to the accompanying drawings.

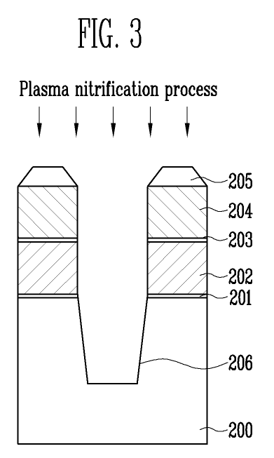

FIGS. 3 to 6 are cross-sectional views illustrating a method of forming an isolation layer of a semiconductor memory device according to an embodiment of the invention.

Referring to FIG. 3, a tunnel insulating layer 201, a conductive layer 202 for a floating gate, a buffer oxide layer 203, a pad nitride layer 204, and a hard mask pattern 205 are formed over a semiconductor substrate 200. The tunnel insulating layer 201 may be deposited to a thickness of 70 to 80 angstrom by means of a well oxidization process. A N₂O annealing process may be then performed on the tunnel insulating layer 201 so that nitride within the tunnel insulating layer 201 is incorporated to reduce the density of trap charges and improve reliability. The conductive layer 202 may have a dual film of an amorphous polysilicon film substantially free from impurities and a polysilicon film containing impurities. The conductive layer 202 may be formed by using SiH₄ gas and PH₃ gas source gases at a temperature of 500 to 550 degrees Celsius. The conductive layer 202 may be deposited to a thickness of 300 to 1500 angstrom. The buffer oxide layer 203 may be formed to a thickness of 30 to 100 angstrom to mitigate stress with the conductive layer 202 and the pad nitride layer 204. The buffer oxide layer 203 may be formed by means of a LP-CVD (low pressure chemical vapor deposition) method. The pad nitride layer 204 may be formed to a thickness of 300 to 1000 angstrom by using a LP-CVD method. The hard mask pattern 205 may be formed to a thickness of 100 to 400 angstrom by using a LP-CVD method.

Thereafter, the pad nitride layer 204, the buffer oxide layer 203, the conductive layer 202, the tunnel insulating layer 201, and the semiconductor substrate 200 are etched by means of an etch process using the hard mask pattern 205 as an etch mask, thus forming a trench 206.

A plasma nitrification annealing process is then performed to prevent trap charges and degradation at the interface and sidewalls of the tunnel insulating layer 201. The plasma nitrification annealing process may be performed by using an Ar gas and an N₂ gas at a temperature of 400 to 500 degrees Celsius. The plasma nitrification annealing process may be performed by using a bias power of 1.8 to 3.3 kW at a pressure of 200 to 500 mT for 5 to 30 sec. At this time, the Ar gas and the N₂ gas preferably have flow rates of 1000 sccm and 200 to 500 sccm, respectively. Similarly, the ratio of the Ar gas flow rate to that of the N₂ gas is preferably 1:0.2 to 0.5.

A post-annealing process is then performed. The post-annealing process may be performed by using N₂ at a temperature of 800 to 900 degrees Celsius for 20 to 30 minutes. The post-annealing process may be performed prior to the plasma nitrification annealing process.

Referring to FIG. 4, an oxidization process is performed to form a wall oxide layer 207 over the entire surface including the trench 206. The wall oxide layer 207 functions to mitigate etch damage generated when etching the trench 206 and to reduce a critical dimension (CD) of an active region. The wall oxide layer 207 may be formed by means of a radical oxidization method in a temperature range of 700 to 1000 degrees Celsius to prevent recrystallization of the conductive layer 202. The wall oxide layer 207 may be formed to a thickness of 20 to 100 angstrom.

After the wall oxide layer 207 is formed, the above post-annealing process and the above plasma nitrification annealing process are preferably carried out under the same conditions.

A first insulating layer 208 is formed over the entire surface including the wall oxide layer 207. The first insulating layer 208 may be formed by using a high-density plasma (HDP) oxide layer.

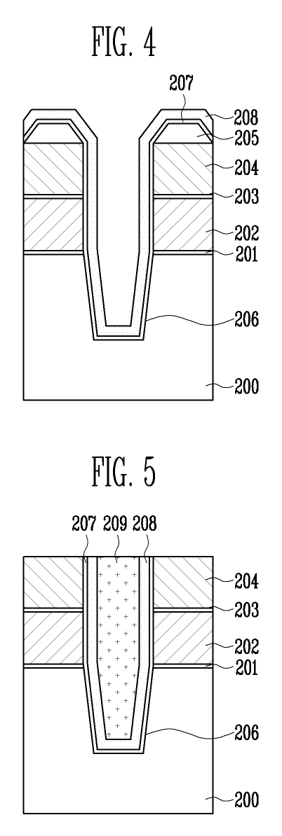

Referring to FIG. 5, a second insulating layer 209 is formed over the entire surface including the first insulating layer 208. The second insulating layer 209 may be formed by using a SOG (spin-on glass), a PSG (phosphosilicate glass) or a BPSG (boron-doped phosphosilicate glass) film. Thereafter, a soft baking process is performed at a temperature of 100 to 300 degrees Celsius for 10 to 100 minutes to improve out-gasing and density properties within the second insulating layer 209. A wet curing process is then performed. A planarizing process, for example CMP process is performed to expose a top surface of the pad nitride layer 204. Thereafter, an etch process is performed to remove the pad nitride layer 204. The etch process may be performed by using phosphoric acid for 10 to 30 minutes.

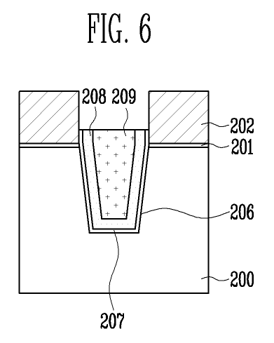

Referring to FIG. 6, a cleaning process is performed to remove the buffer oxide layer 203 and also to adjust the effective field height (EFH) of the isolation layers 208 and 209 to a desired level, thus etching the top surface of the wall oxide 207 and the isolation layers 208 and 209.

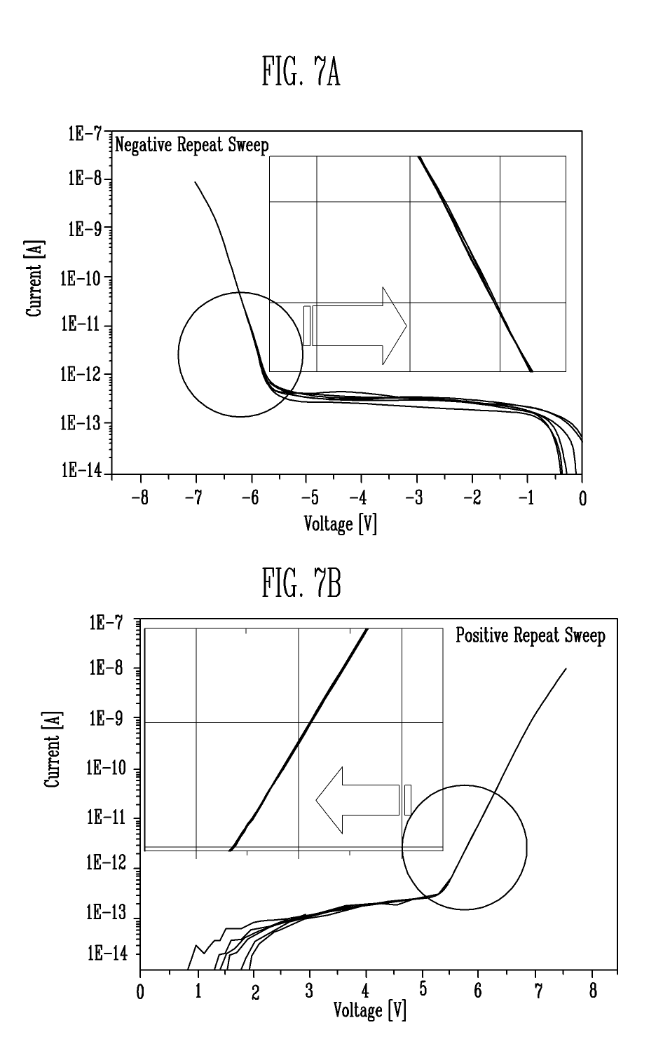

FIGS. 7A and 7B are graphs illustrating the FN current of a tunnel insulation layer according to an embodiment of the invention.

Referring to FIGS. 7A and 7B, if the plasma nitrification annealing process is performed before and after the wall oxide layer is formed, the FN current of the tunnel insulating layer becomes constant with respect to a program and erase bias, so that the ISPP step of a device remains constant.

In accordance with an embodiment of the invention, after a trench is formed in a semiconductor substrate, a plasma nitrification annealing process is performed before and after a wall oxide layer is formed to prevent trap charges and degradation problems at the interface and sidewalls of a tunnel insulating layer due to PSZ stress in a subsequent process. Accordingly, a variation in the ISPP step can be prevented.

Although the foregoing description has been made with reference to a specific embodiment, it is to be understood that changes and modifications of the disclosed method may be made by the skilled artisan without departing from the spirit and scope of the invention as defined in the appended claims.

What is claimed is:

1. A method of forming an isolation layer in a semiconductor memory device, the method comprising:
forming a tunnel insulating layer and a conductive layer for a floating gate over a semiconductor substrate;
selectively etching the conductive layer, the tunnel insulating layer, and the semiconductor substrate to form a trench;
performing a plasma nitrification annealing process;
forming a first insulating layer over the entire resulting surface including the trench; and
depositing a second insulating layer over the entire resulting surface including the first insulating layer.

2. The method of claim 1, further comprising, after the plasma nitrification annealing process and before forming the first insulating layer:
forming a wall oxide layer over the entire resulting surface including the trench; and
performing a second plasma nitrification annealing process.

3. The method of claim 1, further comprising, before the plasma nitrification annealing process,
forming a wall oxide layer over the entire resulting surface including the trench.

4. The method of claim 1, further comprising performing a post-annealing process before forming the first insulating layer and after the plasma nitrification annealing process.

5. The method of claim 4, wherein the post-annealing process comprises using an N₂ gas at a temperature of 800 degrees Celsius to 900 degrees Celsius for 20 minutes to 30 minutes.

6. The method of claim 1, wherein the plasma nitrification annealing process comprises using an Ar gas and an N₂ gas at a temperature of 400 degrees Celsius to 500 degrees Celsius.

7. The method of claim 1, wherein the plasma nitrification annealing process comprises using a bias power of 1.8 kW to 3.3 kW at a pressure of 200 mT to 500 mT for 5 sec. to 30 sec.

8. The method of claim 6, wherein the plasma nitrification annealing process comprises using the Ar gas and the N₂ gas at flow rates selected such that the ratio of the flow rate of the Ar gas to the flow rate of the N₂ gas is 1:0.2 to 0.5.

9. The method of claim 1, wherein the first insulating layer comprises a HDP (high density plasma) oxide layer.

10. The method of claim 1, wherein the second insulating layer comprises a layer selected from the group consisting of an SOG (spin-on gas) layer, a PSG (phosphosilicate glass) layer, and a BPSG (boron-doped phosphosilicate glass) layer.

11. The method of claim 1, further comprising, after forming the conductive layer:
forming a buffer oxide layer, a pad nitride layer, and a hard mask layer over the conductive layer;
wherein the step of selective etching further comprises using the hard mask pattern as a mask to etch the pad nitride layer the buffer oxide layer, the conductive layer, the tunnel insulating layer, and the semiconductor substrate when forming the trench.

12. A method of forming an isolation layer in a semiconductor memory device, the method comprising:
forming a tunnel insulating layer over a semiconductor substrate;
etching the tunnel insulating layer and the semiconductor substrate to form a trench;
performing a plasma nitrification annealing process to prevent trap charges and degradation at an interface and at sidewalls of the tunnel insulating layer;
forming a first insulating layer over the entire resulting surface including the trench; and
depositing a second insulating layer over the entire resulting surface including the first insulating layer.

13. The method of claim 12, further comprising after the plasma nitrification annealing process and before forming the first insulating layer:
forming a wall oxide layer over the entire resulting surface including the trench; and
performing a second plasma nitrification annealing process.

14. The method of claim 12, further comprising, before the plasma nitrification annealing process,
forming a wall oxide layer over the entire resulting surface including the trench.

15. The method of claim 12, wherein the plasma nitrification annealing process comprises using an Ar gas and an N₂ gas at a temperature of 400 degrees Celsius to 500 degrees Celsius.

16. The method of claim 12, wherein the plasma nitrification annealing process comprises using a bias power of 1.8 kW to 3.3 kW at a pressure of 200 mT to 500 mT for 5 sec. to 30 sec.

17. The method of claim 15, wherein the plasma nitrification annealing process comprises using the Ar gas and the N₂ gas at flow rates selected such that the ratio of the flow rate of the Ar gas to the flow rate of the N₂ gas is 1:0.2 to 0.5.

18. A method of forming an isolation layer in a semiconductor memory device, the method comprising:
forming a tunnel insulating layer and a conductive layer for a floating gate over a semiconductor substrate;
selectively etching the conductive layer, the tunnel insulating layer, and the semiconductor substrate to form a trench;
performing a plasma nitrification annealing process;
forming a wall oxide layer over the entire resulting surface including the trench; and
performing a second plasma nitrification annealing process;
forming a first insulating layer over the entire resulting surface including the trench; and
depositing a second insulating layer over the entire resulting surface including the first insulating layer.

19. The method of claim 18, wherein the plasma nitrification annealing process comprises using an Ar gas and an N₂ gas at a temperature of 400 degrees Celsius to 500 degrees Celsius.

20. The method of claim 18, wherein the plasma nitrification annealing process comprises using a bias power of 1.8 kW to 3.3 kW at a pressure of 200 mT to 500 mT for 5 sec. to 30 sec.

21. The method of claim 19, wherein the plasma nitrification annealing process comprises using the Ar gas and the N₂ gas at flow rates selected such that the ratio of the flow rate of the Ar gas to the flow rate of the N₂ gas is 1:0.2 to 0.5.

22. A method of forming an isolation layer in a semiconductor memory device, the method comprising:
forming a tunnel insulating layer and a conductive layer for a floating gate over a semiconductor substrate;
selectively etching the conductive layer, the tunnel insulating layer, and the semiconductor substrate to form a trench;
forming a wall oxide layer over the entire resulting surface including the trench;
performing a plasma nitrification annealing process;
forming a first insulating layer over the entire resulting surface including the trench; and
depositing a second insulating layer over the entire resulting surface including the first insulating layer.

23. The method of claim 22, wherein the plasma nitrification annealing process comprises using an Ar gas and an N₂ gas at a temperature of 400 degrees Celsius to 500 degrees Celsius.

24. The method of claim 22, wherein the plasma nitrification annealing process comprises using a bias power of 1.8 kW to 3.3 kW at a pressure of 200 mT to 500 mT for 5 sec. to 30 sec.

25. The method of claim 23, wherein the plasma nitrification annealing process comprises using the Ar gas and the N₂ gas at flow rates selected such that the ratio of the flow rate of the Ar gas to the flow rate of the N₂ gas is 1:0.2 to 0.5.
